(19) United States
(12) Patent Application Publication
(10) Pub. No.: US 2026/0309765 A1
(43) Pub. Date: Oct. 8, 2026

(54) LOW COST, HIGH ACCURACY & STANDARDS COMPLIANT ISOLATION PARAMETER TEST SYSTEM AND METHOD FOR SEMICONDUCTOR DEVICES

(71) Applicant: Texas Instruments Incorporated, Dallas, TX (US)

(72) Inventors: Himalaya Pramanick, BENGALURU (IN); Mohana Krishna Bolanthakodi Bhat, BANGALORE (IN); Sudhir Adinarayana, BANGALORE (IN); Weng Shyan Aik, SUBANG JAYA (MY); Kadamati Mohana valli, VIZIANAGARAM (IN); Pei Fang Tie, Kuala Lumpur (MY); Shruti Gupta, Bengaluru (IN); Xiang Gin Cheah, PETALING JAYA (MY)

(21) Appl. No.: 19/173,063

(22) Filed: Apr. 8, 2025

(51) Int. Cl. G01R 31/12; G01R 1/04

(52) U.S. Cl. CPC G01R 31/1227; G01R 1/0408

(57) ABSTRACT

A system includes a socket with first and second terminals configured to connect to respective terminals of an electronic device, an AC voltage source having a first output coupled to the first terminal and a second output coupled to a reference node, a first circuit having a high pass filter coupled between the second terminal and a first analog to digital converter (ADC), a second circuit having a low pass filter coupled between the second terminal and a second ADC, a third circuit having another high pass filter coupled between second terminal and a third ADC, and a processor to determine a partial discharge based on samples from the first ADC, a leakage current based on samples from the second ADC, and an arc current based on samples from the third ADC.

### BACKGROUND

Manufacturing electronic devices such as integrated circuits, high voltage isolation devices, etc. often requires testing for standards verification. For example, compliance with IEC 60747-17, VDE 0884-17 and UL 1577 calls for measurements of semiconductor device partial discharge, leakage current, arcing and working (stress) voltage before shipment to customers. Isolation testing of every device adds significant test cost, and current solutions use separate measurement equipment for each test. This leads to longer testing times and increased capital expenditure to support standards verification for electronic devices with high voltage isolation features.

### SUMMARY

In one aspect, a system includes a socket with first and second socket terminals configured to connect to respective first and second terminals of an electronic device, an AC voltage source having a first output terminal coupled to the first socket terminal and a second output terminal coupled to a reference node, a first circuit having a first high pass filter coupled between the second socket terminal and a first analog to digital converter, a second circuit having a low pass filter coupled between the second socket terminal and a second analog to digital converter, a third circuit having a second high pass filter coupled between second socket terminal and a third analog to digital converter, and a processor connected to outputs of the respective first, second, and third analog to digital converters, the processor configured to determine a partial discharge of the electronic device based on samples from the first analog to digital converter, determine a leakage current of the electronic device based on samples from the second analog to digital converter, and determine an arc current of the electronic device based on samples from the third analog to digital converter.

In another aspect, a contactor interface board for testing an electronic device installed in a socket includes an AC voltage source having a first output terminal coupled to a first socket terminal and a second output terminal coupled to a reference node, a first circuit having a first high pass filter coupled between a second socket terminal and a first analog to digital converter, a second circuit having a low pass filter coupled between the second socket terminal and a second analog to digital converter, a third circuit having a second high pass filter coupled between second socket terminal and a third analog to digital converter, and a processor connected to outputs of the respective first, second, and third analog to digital converters, the processor configured to determine a partial discharge of the electronic device based on samples from the first analog to digital converter, determine a leakage current of the electronic device based on samples from the second analog to digital converter, and determine an arc current of the electronic device based on samples from the third analog to digital converter.

In a further aspect, a method includes applying an AC input signal to a first socket terminal of a socket, determining a partial discharge of an electronic device installed in the socket based on a high pass filtered voltage of a second socket terminal responsive to application of the AC input signal to the first socket terminal, and concurrently with determining the partial discharge, determining a leakage current of the electronic device based on a low pass filtered voltage of the second socket terminal responsive to application of the AC input signal to the first socket terminal.

### BRIEF DESCRIPTION OF THE DRAWINGS

FIG. 1 is a perspective system drawing of a manufacturing test system for testing electrical operating parameters of electronic devices.

FIG. 1A is a schematic diagram of a contactor interface board and a load board of the system of FIG. 1.

FIG. 1B is a perspective view of a contactor interface board and an installed load board in the system of FIG. 1.

FIG. 2 is a flow diagram of an electronic device manufacturing method with electronic device testing based on concurrent signal processing.

FIG. 3 is a graph of an example device under test (DUT) output signal.

FIG. 4 is a graph of an example partial discharge waveform in the system of FIG. 1.

FIG. 5 is a graph of an example leakage current waveform in the system of FIG. 1.

FIG. 6 is a graph of an example arc waveform in the system of FIG. 1.

### DETAILED DESCRIPTION

In the drawings, like reference numerals refer to like elements throughout, and the various features are not necessarily drawn to scale. Also, the term "couple" or "couples" includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means +/- 10 percent of the stated value. One or more structures, features, aspects, components, etc., may be referred to herein as first, second, third, etc., such as first and second terminals, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

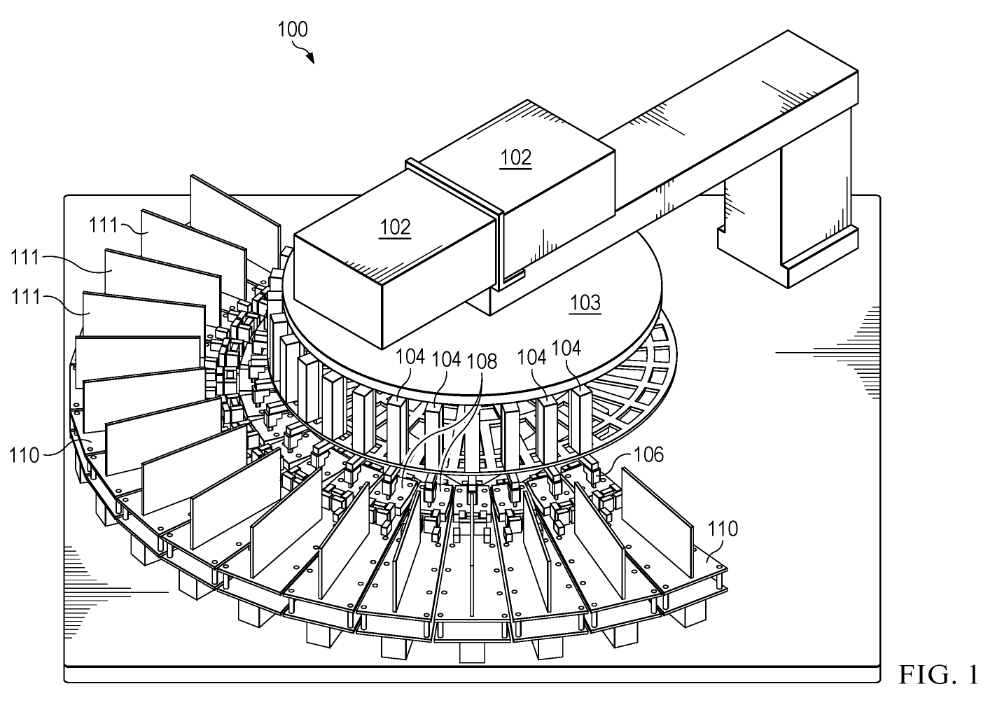

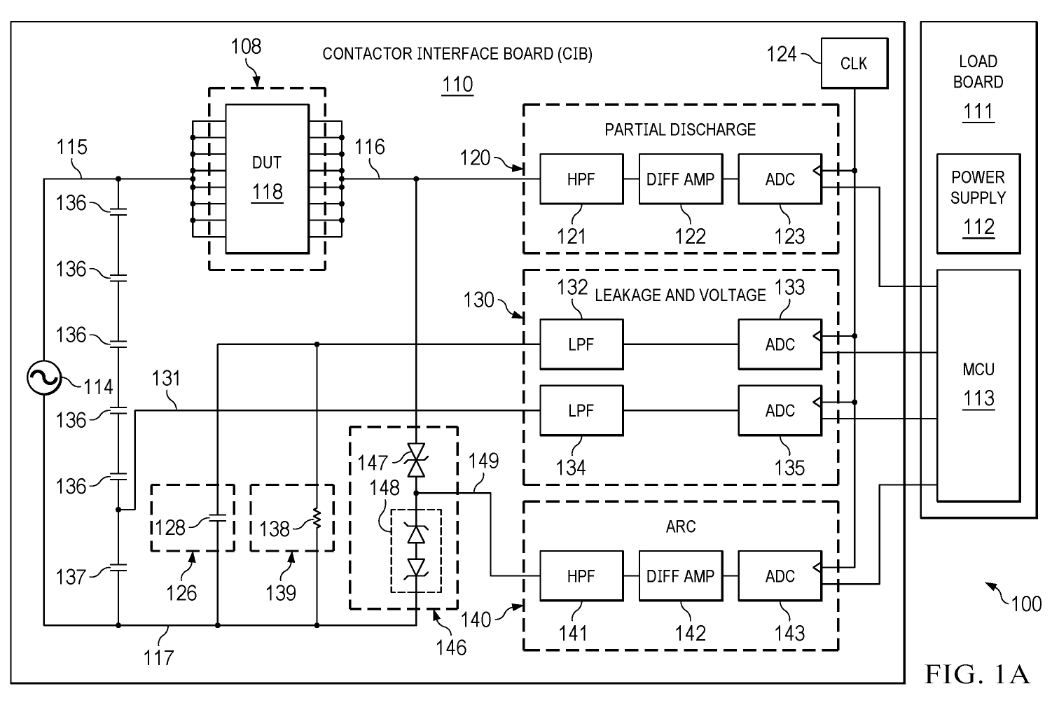

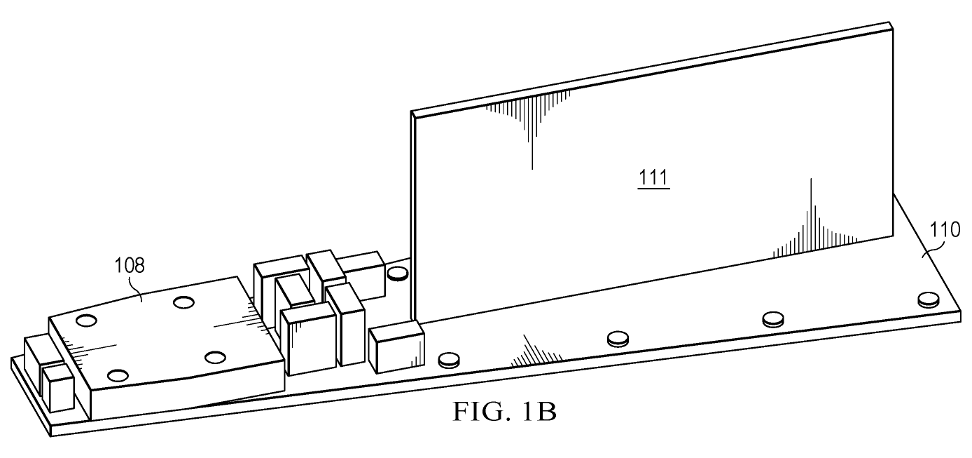

FIGS. 1-1B show an electronic device manufacturing test system 100 for testing electrical operating parameters of electronic devices. FIG. 1 shows a top perspective view of the test system 100 with a central controller 102 mounted on a turret 103. Side mounted motor drivers 104 position turret handlers 106 that automatically install and remove electronic devices (also referred to as devices under test or DUTs) to and from device sockets 108 or respective contactor interface boards 110 (CIBs). As further shown in FIG. 1B, a load board 111 is installed in each of the individual CIBs 110. The example system 100 has 16 units with respective CIB 110, load board 111 and device socket 108 to accommodate concurrent testing of 16 electronic devices. Unlike prior test systems that required a lengthy cable connection from the test equipment to each individual DUT (e.g., approximately 2 m of cable length), the example system 100 provides automated socket insertion and removal with the turret 103 rotatable about a central axis to perform 16 concurrent DUT retrievals from a loading position and rotation to align with the DUT sockets 108 for automated installation of electronic devices for testing in a corresponding one of the CIBs 110.

The system 100 also provides concurrent testing or measurement of all the isolation parameters at once, with 16 DUTs tested in parallel. This system configuration greatly reduces device testing time and thus lowers the device manufacturing cost. In addition, the example system 100 eliminates cable connections found in conventional test setups and provides close proximity of a tested device to the measurement circuitry of the associated to reduce adverse effects such as attenuation and noise associated with lengthy cables for partial discharge and other isolation testing to provide low noise measurements with high accuracy and high signal to noise ratio (SNR).

FIG. 1A shows a schematic diagram of an example CIB 110 and an installed load board 111 of the test system 100. The CIB 110 includes the device socket 108 with a first socket terminal 115 and a second socket terminal 116. In the illustrated example, the socket 108 has two rows of 8 socket terminals configured to individually engage with a corresponding device terminal along two opposite sides of the tested electronic device 118 (DUT) installed in the socket 108. The terminals of each row of the socket 108 in the illustrated example are electrically connected to one another to provide a first terminal connection 115 connected to the first row of device leads and a second terminal connection 116 connected to the second row of device leads of an installed electronic device (DUT) 118. In other implementations, the socket 108 can have different numbers of pins with first and second socket terminals 115 and 116 configured to connect to respective first and second terminals of an installed electronic device 118.

An AC voltage source 114 has a first output terminal coupled to the first socket terminal 115, as well as a second output terminal coupled to a reference node 117. In one example, the reference node 117 can be a ground or common terminal of the test system 100, although not a requirement of all possible implementations. In one example, the AC voltage source is powered by connections to the turret handler 106 (FIG. 1) and provides an AC voltage signal across the first and second output terminals, which can be sinusoidal or other alternating signal waveform, and can include one or more spikes. In another implementation, the AC voltage source 114 can be external to the CIB 110, and the CIB 110 can include terminal connections to allow connections of an external AC voltage source 114 to the first terminal connection 115 and to the reference node 117.

In operation in one example, the AC voltage source 114 is configured to apply an AC input signal to the first terminal connection 115 (e.g., a voltage signal referenced to the second output terminal of the AC voltage source 114 reference to the voltage of the reference node 117). In one implementation, the AC voltage source 114 is configured to apply the AC input signal at a single amplitude, such as a high frequency AC signal with a single amplitude (e.g., within 10% of a designated RMS or peak to peak amplitude) with or without a spike. In this or another implementation, the AC voltage source 114 is configured to apply the AC input signal with a spike to facilitate partial discharge testing. In one example, the spike is superimposed on an otherwise approximately constant amplitude AC waveform.

The test system 100 advantageously applies a single AC input signal to the DUT 118 and concurrently filters and measures responsive signals using multiple specifically tailored circuits 120, 130, and 140 in the CIB 110 to obtain multiple measurements for evaluating multiple operational parameters associated with the isolation performance of the tested DUT 118 in a single test. This provides significant cost savings in terms of speeding up manufacturing production testing compared with conventional isolation testing approaches that apply multiple separate AC input signals, typically in separate cable connected test equipment to perform individual measurements one of the time.

The CIB 110 in the illustrated example includes a first circuit 120 with a first high pass filter 121 (e.g., labeled “HPF” in FIG. 1A). The first high pass filter 121 is coupled between the second socket terminal 116 and a first analog to digital converter 123 (e.g., labeled “ADC”). The first circuit 110 in this example has a differential amplifier 122 coupled between an output of the first high pass filter 121 and an input of the first analog to digital converter 123, although not a requirement of all possible implementations. An input of the first high pass filter 121 is coupled to the second socket terminal 116, and an output of the first high pass filter 121 is configured to provide a first high pass filtered signal to the input of the differential amplifier 122 (e.g., or directly to an input of the first analog to digital converter 123) based on the voltage signal at the second socket terminal 116 responsive to the AC input signal at the first socket terminal 115 from the AC voltage source 114. In one example, the first high pass filter 121 has a cutoff frequency of approximately 1 MHz or more.

The first analog to digital converter 123 has a clock input coupled to receive a clock signal from a clock circuit 124 of the CIB 110 (e.g., labeled “CLK” in FIG. 1A). The first analog to digital converter 123 has a data output that provides digital samples of the received first high pass filtered signal. As further shown in FIG. 1A, the load board 111 includes a power supply 112 as well as a processor (e.g., labeled “MCU”). The output of the first analog to digital converter 123 is coupled to an input of the processor 113 to provide the samples of the first high pass filtered signal for processing and evaluation to determine the partial discharge performance of the tested DUT 118.

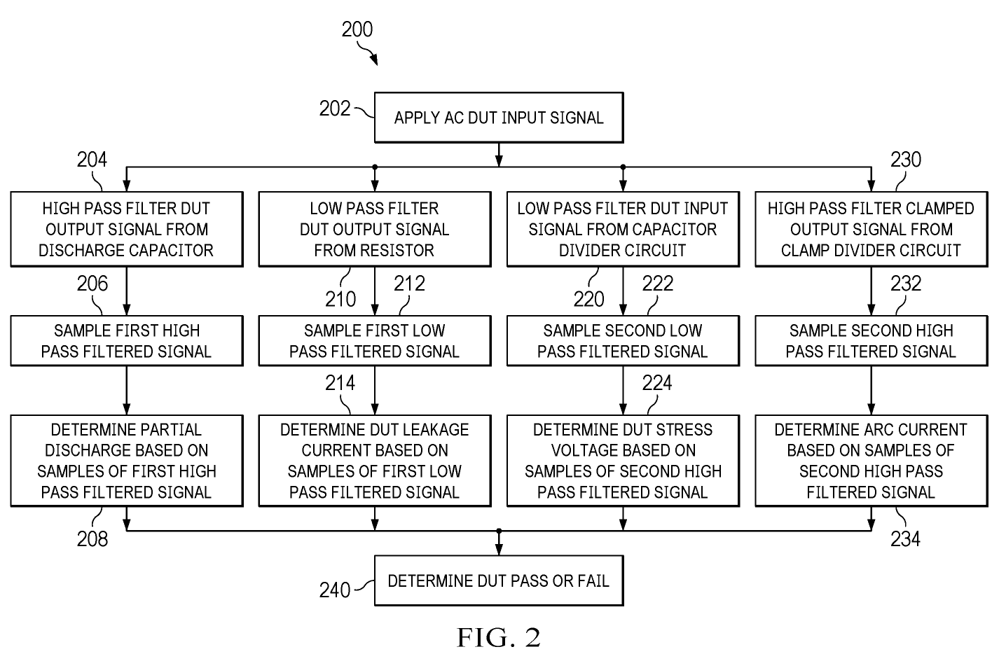

As further shown in FIG. 1A, the CIB 110 in this example also includes a charge collection circuit 126 with a capacitor 128 configured to collect charge in response to a partial discharge event associated with the tested DUT 118. The capacitor 128 as an upper or first capacitor terminal coupled to the first socket terminal 115 and a lower or second capacitor terminal coupled to the reference node 117. The first high pass filter 121 of the first circuit 120 filters the voltage signal of the second socket terminal 116 (e.g., the voltage at the first capacitor terminal of the capacitor 128). The processor 113 receives the samples of the first filtered signal from the first analog to digital converter 123 and is configured to determine a partial discharge of the electronic device 118 based on the samples from the first analog to digital converter 123, as described further below in connection with FIGS. 2-4.

The example CIB 110 includes a second circuit 130 with a first low pass filter 132 coupled between the second socket terminal 116 and a second analog to digital converter 133. An input of the first low pass filter 132 is coupled to the second socket terminal 116. An output of the first low pass filter 132 is configured to provide a first low pass filtered signal to an input of the second analog to digital converter 133 based on the voltage signal at the second socket terminal 116 responsive to the AC input signal at the first socket terminal 115. In one example, the first low pass filter 132 has a cutoff frequency of approximately 100 Hz or less.

The CIB 110 also includes a leakage sense circuit 139 with a resistor 138 used to measure the leakage current. The resistor 138 has a first resistor terminal coupled to the second socket terminal 116 and a second resistor terminal coupled to the reference node 117. The resistor develops a voltage at the first resistor terminal based on leakage current flowing from the DUT 118 in response to the AC input signal applied by the AC voltage source 114.

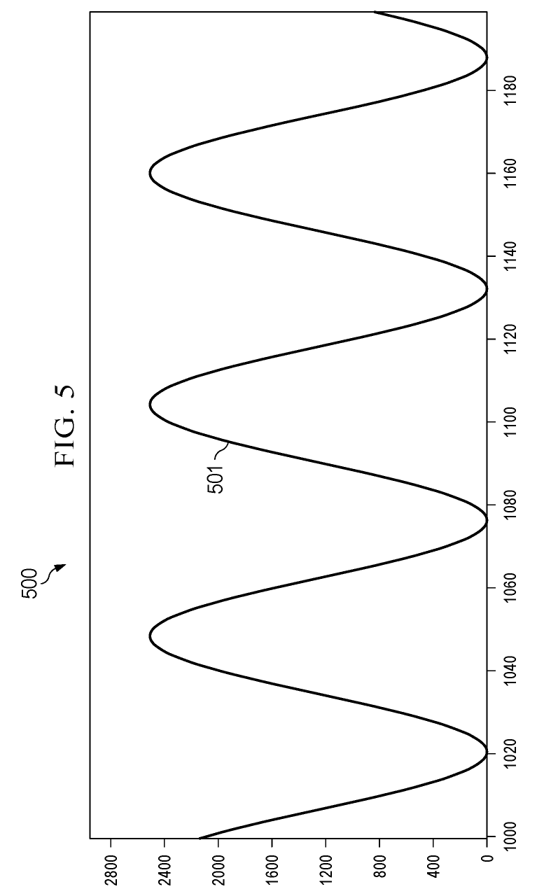

The second analog to digital converter 133 has a clock input coupled to receive the clock signal from the clock circuit 124. The second analog to digital converter 133 has a data output that provides digital samples of the received first low pass filtered signal from the first low pass filter 132. The output of the second analog to digital converter 133 is coupled to an input of the processor 113 to provide the samples of the first low pass filtered signal. The processor 113 is configured to determine the leakage current of the electronic device 118 based on samples from the second analog to digital converter 133, as described further below in connection with FIGS. 2 and 5.

The CIB 110 in FIG. 1A also includes a third circuit 140 for arc detection. The third circuit 140 has a second high pass filter 141 coupled between second socket terminal 116 and a third analog to digital converter 143. In one example, the second high pass filter 141 has a cutoff frequency of approximately 1 MHz or more, such as approximately 10 MHz or more in one implementation. An input of the second high pass filter 141 is coupled to the second socket terminal 116. An output of the second high pass filter 141 is configured to provide a second high pass filtered signal to an input of the third analog to digital converter 143 based on the voltage signal at the second socket terminal 116 responsive to the AC input signal at the first socket terminal 115.

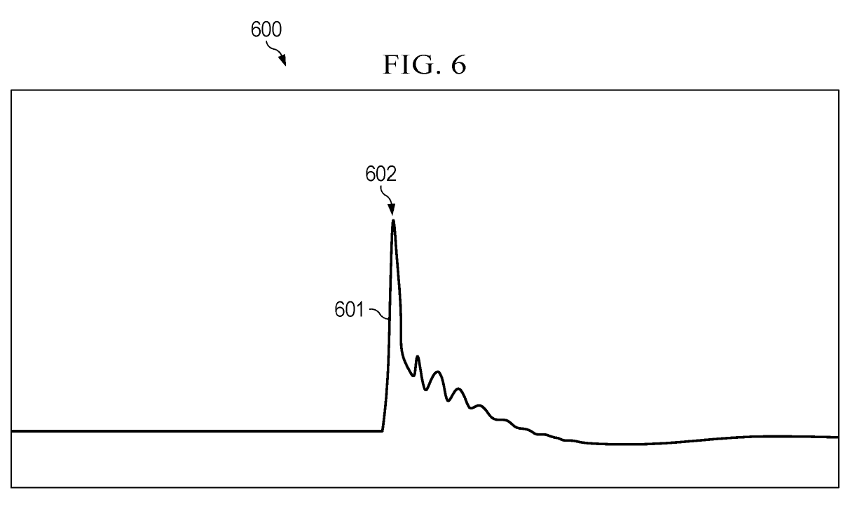

In the illustrated example, the third circuit 140 has a differential amplifier 142 coupled between an output of the second high pass filter 141 and an input of the third analog to digital converter 143. The second high pass filter 141 provides a second high pass filtered signal to the third analog to digital converter 143 directly or to the input of the differential amplifier 142. The third analog to digital converter 143 has a data output that provides digital samples of the received second high pass filtered signal to the processor 113 of the load board 111 for arc detection in response to the applied AC signal from the AC voltage source 114. The processor 113 is connected to the output of the third analog to digital converter 143. The processor 113 is configured to determine an arc current of the electronic device 118 based on samples from the third analog to digital converter 143 as discussed further below in connection with FIGS. 2 and 6.

In one example, the CIB 110 also includes a clamp circuit 146 coupled between the second socket terminal 116 and the reference node 117. The processor 113 is configured to determine an arc current of the electronic device 118 based on a high pass filtered voltage of the clamp circuit 146 responsive to application of the AC input signal to the first socket terminal 115. An input of the second high pass filter 141 is coupled to the clamp circuit 146. Any suitable clamp circuit 146 can be used. The clamp circuit 146 in the illustrated example of FIG. 1A includes respective first and second diodes 147 and 148 connected in series between the second socket terminal 116 and the reference node 117. In one example, the first and second diodes 147 and 148 each have a pair of Zener diodes connected in series with one another. In this example, the first diode 147 has respective cathodes coupled to one another, a first anode connected to the second socket terminal 116, and another anode connected to a tap node 149 between the first and second diodes 147 and 148. The second diode 148 in the illustrated example includes another pair of series connected Zener diodes with respective anodes coupled to one another, a first cathode connected to the tap node 149, and a second cathode connected to the reference node 117. The input of the second high pass filter 141 of the third circuit 140 is coupled to the tap node 149. In operation, the clamp circuit 146 provides clamping to protect the second socket terminal 116 from significant overvoltage conditions and the clamp circuit tap node 149 is used to measure the arc.

As further shown in FIG. 1A, the second circuit 130 can also include further circuitry to facilitate measurement of the DUT stress voltage (also referred to as working voltage) in response the AC input signal applied by the AC voltage source 114. In one example, the second circuit 130 of the CIB 110 includes a second low pass filter 134 coupled between the first socket terminal 115 and a fourth analog to digital converter 135. In one example, the second low pass filter 134 has a cutoff frequency of approximately 100 Hz or less. The second low pass filter 134 has an output that provides a second low pass filtered signal to an input of the fourth analog to digital converter 135. The CIB 110 in this example also includes a capacitor divider circuit 136, 137 with one or more upper capacitors 136 and one or more lower capacitors 137 to form a capacitor voltage divider circuit. The capacitors 136 and 137 are coupled in series with one another between the first socket terminal 115 and the reference node 117. A tap node 131 of the capacitive divider circuit 136, 137 is coupled to the input of the second low pass filter 134. Any suitable tap point can be used between two adjacent capacitors of the capacitive divider circuit 136, 137. The processor 113 in one example is configured to determine a stress or working voltage of the DUT 118 based on samples from the fourth analog to digital converter 135, as described further below in connection with FIGS. 2 and 5.

The circuitry 120, 130, 140 of the CIB 110 advantageously performs two or more isolation parameter measurements of the tested DUT 118 concurrently in response to a single applied AC input signal from the AC voltage source 114. The illustrated examples measure electrical signals from the second socket terminal 116 (e.g., and also from the input capacitive divider circuit 136, 137 in certain examples) and the measured way forms are selectively filtered to split the sensed signals in the frequency domain to obtain multiple measurements in parallel (e.g., simultaneously and/or concurrently). The processor 113 obtains digital samples from multiple analog to digital converters 123, 133, 135 and/or 143 and performs one or more evaluations of the samples to determine any two or more parameters such as partial discharge, leakage current, stress (e.g., working) voltage and/or arc detection or other operational parameters of the tested DUT 118.

The example system 100 of FIGS. 1-1B can accommodate parallel testing of up to 16 DUTs1 18 in corresponding contactor interface boards 110 (e.g., FIG. 1), with each parallel test yielding multiple concurrent measurements to greatly speed up device testing during manufacturing. The AC voltage source 114 in certain examples provides an AC input signal to the first socket terminal 115, and the analog to digital converters 123, 133, 135, 143 concurrently sample a filtered signal of the respective first, second and third circuits 120, 130 and 140 responsive to the AC input signal at the first socket terminal 115.

As shown in FIGS. 1 and 1B, moreover, the example CIBs 110 are compact circuit boards (e.g., approximately 50 mm x 370 mm) with integrated filtering and other measurement circuitry along with one or more analog to digital converters. In other implementations, two or more of the analog to digital converters 123, 133, 135, 143 can be combined, for example, using high-speed analog multiplexer circuitry to receive the filtered signals of the circuits 120, 130 and 140, with the multiplexer selectively coupling a selected one of multiple filtered signals to the input of a shared analog to digital converter. The processor 113 computes various test parameters of the tested DUT 118 in one example and reports a pass and/or fail result for individual tested parameters for each tested DUT 118. The CIB circuitry occupies a small amount of area and does not use any external measurement equipment to facilitate extreme parallel testing, where certain examples can reduce test cost by a factor of five or more compared to previous solutions that require separate measurement equipment. In addition, the described examples are easily scalable to further reduce test cost and increase test speed.

In one example, the individual CIBs 110 include the AC voltage source 114, the first circuit 110 having the first high pass filter 121 coupled between the second socket terminal 116 and the first analog to digital converter 123, the second circuit 130 having the first low pass filter 132 coupled between the second socket terminal 116 and the second analog to digital converter 133, as well as the third circuit 140 having the second high pass filter 141 coupled between second socket terminal 116 and the third analog to digital converter 143, and the processor 113 connected to outputs of the respective first, second, and third analog to digital converters 123, 133, 135, 143. The processor 113 determines the partial discharge of the electronic device 118 based on samples from the first analog to digital converter 123, determines the leakage current of the electronic device 118 based on samples from the second analog to digital converter 133, and determines an arc current of the electronic device 118 based on samples from the third analog to digital converter 143.

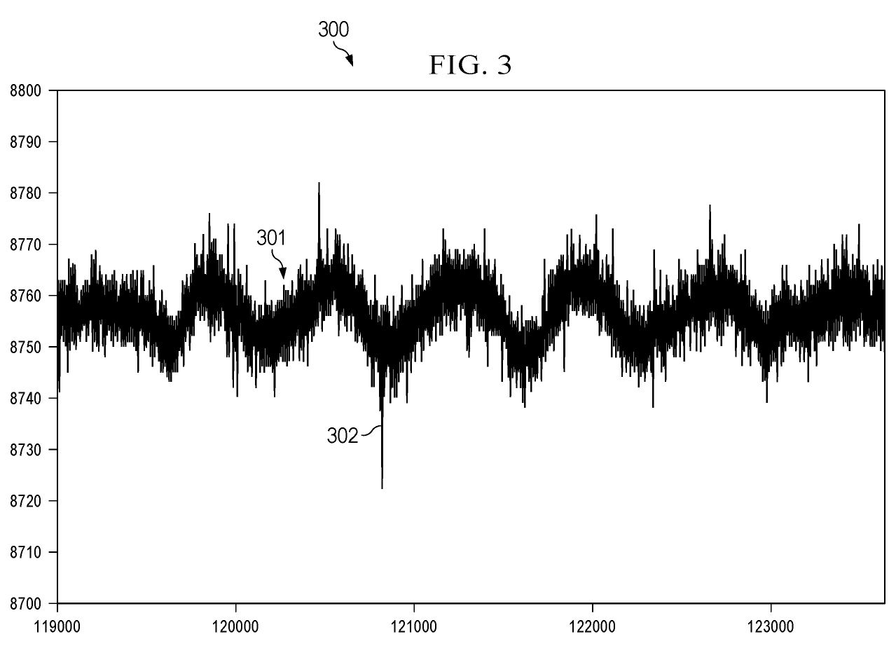

Referring also to FIGS. 2-6, FIG. 2 shows an example electronic device manufacturing method 200 with electronic testing and device classification based on concurrent measurement of multiple electrical operating parameters. FIGS. 3-6 illustrate example signals in waveforms in an implementation of the system 100. The method 200 is described with references to the test system 100 described above in connection with FIGS. 1-1B.

The method 200 begins at 202 in FIG. 2 with applying an AC input signal to the first socket terminal 115 of the socket 108. In one example, the AC voltage source 114 applies the AC input signal at 202 at a single amplitude. In this or another example, the AC voltage source 114 applies the AC input signal with a spike for partial discharge testing, although not a requirement of all possible implementations. The AC voltage source 114 in certain implementations applies the single AC input signal with an approximately constant amplitude for sufficient time to allow the filtering and sampling of the resulting signals at the second socket terminal 116 and the capacitive divider tap node 131 by the circuits 120, 130, and 140 to facilitate concurrent testing of two or more parameters associated with isolation performance of the DUT 118.

The method 200 illustrates one example implementation including concurrent determination of partial discharge of the DUT 118 at 204-208, determination of DUT leakage current at 210-214, determination of DUT stress voltage at 220-224, and determination of DUT arc current at 230-234, followed by determination at 240 of a DUT pass or fail result. The concurrent measurement and parameter determination are performed at the local CIB 110 and load board 111 of each station of a multiple station system, such as the 16 station system 100 of FIGS. 1-1B.

With respect to partial discharge measurement and testing, the method 200 includes high pass filtering the DUT output signal at 204 in FIG. 2 (e.g., using the first high pass filter 121 in FIG. 1A), for example, the voltage of the upper terminal of the discharge capacitor (e.g., circuit 126). At 206, the partial discharge measurement includes sampling the first high pass filtered signal from the output of the first high pass filter 121, for example, using the first analog to digital converter 123 in FIG. 1A.

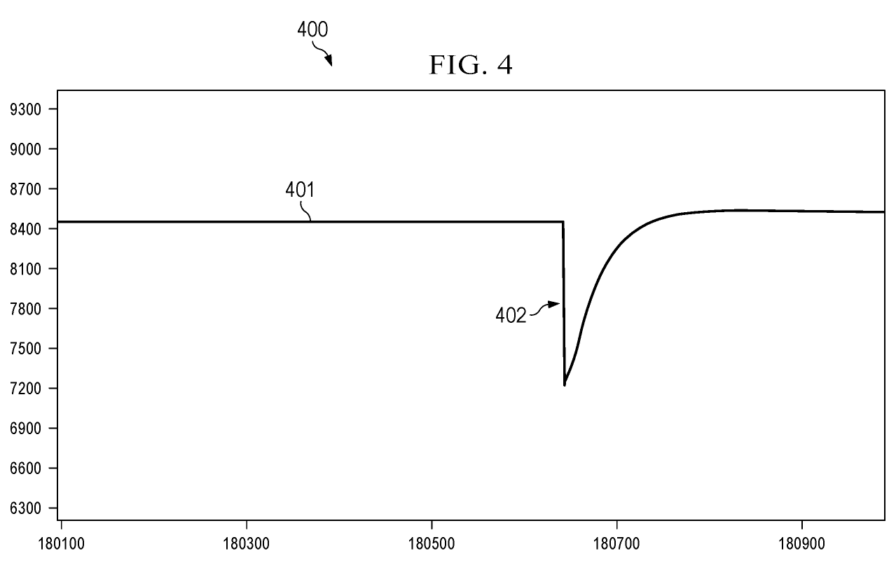

At 208, the method 200 includes determining the partial discharge of the installed electronic device or DUT 118 based on the high pass filtered voltage of the second socket terminal 116 (e.g., using the processor 113 of the load board 111), responsive to application of the AC input signal to the first socket terminal 115 at 202. FIG. 3 shows a graph 300 of an example device under test (DUT) output signal 301, including a negative spike 302 corresponding to a partial discharge event associated with the DUT 118. FIG. 4 shows a graph 400 with an example partial discharge waveform 401 having a spike 402 in the system of FIG. 1. In one example, the waveform 401 corresponds to the first high pass filtered signal provided at the output of the first high pass filter 121 and the first circuit 120, which is buffered by the differential amplifier 122 and sampled by the first analog to digital converter 123 in FIG. 1A. In one implementation, the processor 113 evaluates the samples from the first analog to digital converter 123 at 208 in FIG. 2 and determines the peak amplitude of the spike 402 and the waveform 401, which represents the peak partial discharge current of the DUT 118 in response to the applied AC input signal from the AC voltage source 114.

The method 200 includes leakage current measurement and determination, concurrently with determining the partial discharge. At 210 in FIG. 2, one example includes low pass filtering the DUT output signal from the resistor (e.g., resistor 138 in FIG. 1A, using the first low pass filter 132). The first low pass filtered signal is sampled at 212 (e.g., using the second analog to digital converter 133). At 214, the DUT leakage current is determined based on the samples of the first low pass filtered voltage signal of the second socket terminal 116 (e.g., using the processor 113), responsive to application of the AC input signal to the first socket terminal 115. FIG. 5 shows a graph 500 with an example leakage current waveform 501 in the system of FIG. 1. In one example, the wafer 501 corresponds to the first low pass filtered signal from the first low pass filter 132 in FIG. 1A, which is sampled at 212 by the second analog to digital converter 133. In one example, the processor 113 determines the DUT leakage current at 214 based on the amplitude of the first low pass filtered signal (e.g., curve 501 in FIG. 5), which represents the leakage current of the DUT 118 measured as a voltage across the sense resistor 138 in FIG. 1A.

The method 200 in FIG. 2 in some examples also includes DUT stress voltage determination at 220-224, concurrently with any included leakage current measurements and partial discharge measurements. At 220, the method 200 includes low pass filtering the DUT input signal from the capacitor divider circuit (e.g., low pass filtering the signal at the tap node 131 of the capacitive divider 136, 137 using the second low pass filter 134 In FIG. 1A). At 222 in FIG. 2, the method 200 includes sampling the second low pass filtered signal, using the fourth analog to digital converter 135. At 224, the processor 113 determines the DUT stress voltage based on the second low pass filtered voltage of the first socket terminal 115 responsive to application of the AC input signal to the first socket terminal 115. In one example, the second low pass filtered signal from the second low pass filter 134 has an amplitude that represents the working voltage or stress voltage of the DUT 118 that was applied to the first socket terminal 115 during testing.

The method 200 in certain implementations also includes our current determination at 230-234 in FIG. 2. At 230, a clamp output signal from the clamp divider circuit 146 is high pass filtered, for example, using the second high pass filter 141 of the third circuit 140 in FIG. 1A. The second high pass filter 141 provides the second high pass filtered signal through any included differential amp 142 or directly to the input of the third analog to digital converter 143, which samples the second high pass filtered signal at 232 in FIG. 2. At 234, the processor 113 determines the arc current of the DUT 118 based on the high pass filtered voltage of the clamp circuit 146 responsive to application of the AC input signal to the first socket terminal 115. FIG. 6 shows a graph 600 of an example arc waveform 601 in the system 100 of FIG. 1 with a spike 602 that represents the second high pass filtered signal that is sampled by the third analog to digital converter 143. In one example, the processor 113 evaluates the samples from the third analog to digital converter 143 and detects the presence of the spike 602. In one implementation, the processor 113 determines whether the sampled second high pass filtered signal exceeds a certain threshold, and if so identifies the test as having an arc event and determines the level of the peak 602 as corresponding to a peak arc current experienced by the DUT 118 during the testing.

Described examples provide high-speed, highly parallel testing systems 100, contactor interface boards 110 and methods 200 which can be advantageously employed to shorten test times for electronic device manufacturing by concurrently measuring multiple parameters associated with tested device isolation performance. In addition, the described examples facilitate improved measurement accuracy by incorporation of the circuits 120, 130, 140, 126, 136 and 146 directly on to the contactor interface board without any lengthy cable connections during testing. The integration of the measurement circuitry into the CIB 110 provides close proximity to the DUT 118 and avoids or mitigate inaccuracies associated with partial discharge of the cable as used in conventional test apparatus. These and other advantages provide cost savings during electronic device manufacturing, as well as low signal to noise ratio measurements without noise and attenuation associated with test cables in prior systems. Other benefits may include the ability to reduce calibration frequency and reduce test system downtime due to the higher accuracy obtained by the described system 100. This downtime reduction in certain implementations can be like a factor of five or more. In addition, the described systems perform multiple measurements using a single interface circuit 110 by separating one or more runaway forms into multiple different frequency domains, while reducing the overall system component size significantly, thereby resulting in lower capital expenditures on test equipment compared to prior techniques. In addition, the described systems provide robust thorough evaluation of device compliance with multiple standards (e.g., IEC 60747-17, VDE 0884-17, UL 1577, etc.).

Modifications are possible in the described examples, and other implementations are possible, within the scope of the claims.

What is claimed is:

1. A system, comprising:
a socket with first and second socket terminals configured to connect to respective first and second terminals of an electronic device;
an AC voltage source having a first output terminal coupled to the first socket terminal and a second output terminal coupled to a reference node;
a first circuit having a first high pass filter coupled between the second socket terminal and a first analog to digital converter;
a second circuit having a low pass filter coupled between the second socket terminal and a second analog to digital converter;
a third circuit having a second high pass filter coupled between second socket terminal and a third analog to digital converter; and
a processor connected to outputs of the respective first, second, and third analog to digital converters, the processor configured to determine a partial discharge of the electronic device based on samples from the first analog to digital converter, determine a leakage current of the electronic device based on samples from the second analog to digital converter, and determine an arc current of the electronic device based on samples from the third analog to digital converter.

2. The system of claim 1, wherein the AC voltage source is configured to provide an AC input signal to the first socket terminal, and the first, second and third analog to digital converters concurrently sample a filtered signal of the respective first, second and third circuits responsive to the AC input signal at the first socket terminal.

3. The system of claim 1, wherein the first circuit has a differential amplifier coupled between an output of the first high pass filter and an input of the first analog to digital converter.

4. The system of claim 3, wherein an input of the first high pass filter is coupled to the second socket terminal, and an output of the first high pass filter is configured to provide a first high pass filtered signal based on a voltage signal at the second socket terminal responsive to an AC input signal at the first socket terminal.

5. The system of claim 1, wherein the first high pass filter has a cutoff frequency of approximately 1 MHz or more.

6. The system of claim 1, further comprising a capacitor with a first capacitor terminal coupled to the first socket terminal and a second capacitor terminal coupled to the reference node.

7. The system of claim 1, wherein an input of the low pass filter is coupled to the second socket terminal, and an output of the low pass filter is configured to provide a low pass filtered signal based on a voltage signal at the second socket terminal responsive to an AC input signal at the first socket terminal.

8. The system of claim 7, further comprising a resistor with a first resistor terminal coupled to the second socket terminal and a second resistor terminal coupled to the reference node.

9. The system of claim 1, wherein:
the low pass filter is a first low pass filter; and
the system further comprises a capacitor divider circuit coupled between the first socket terminal and the reference node;
the second circuit includes a second low pass filter coupled between the capacitor divider circuit and a fourth analog to digital converter;
the processor is connected to an output of the fourth analog to digital converter; and
the processor is configured to determine a stress voltage of the electronic device based on samples from the fourth analog to digital converter.

10. The system of claim 9, wherein the second low pass filter has a cutoff frequency of approximately 100 Hz or less.

11. The system of claim 1, wherein the low pass filter has a cutoff frequency of approximately 100 Hz or less.

12. The system of claim 1, wherein the third circuit has a differential amplifier coupled between an output of the second high pass filter and an input of the third analog to digital converter.

13. The system of claim 1, wherein the second high pass filter has a cutoff frequency of approximately 1 MHz or more.

14. The system of claim 1, further comprising a clamp circuit coupled between the second socket terminal and the reference node, wherein an input of the second high pass filter is coupled to the clamp circuit.

15. The system of claim 14, wherein the clamp circuit includes first and second diodes connected in series between the second socket terminal and the reference node, and the input of the second high pass filter is coupled to a tap point between the first and second diodes.

16. A contactor interface board for testing an electronic device installed in a socket, comprising:
an AC voltage source having a first output terminal coupled to a first socket terminal and a second output terminal coupled to a reference node;
a first circuit having a first high pass filter coupled between a second socket terminal and a first analog to digital converter;
a second circuit having a low pass filter coupled between the second socket terminal and a second analog to digital converter;
a third circuit having a second high pass filter coupled between second socket terminal and a third analog to digital converter; and
a processor connected to outputs of the respective first, second, and third analog to digital converters, the processor configured to determine a partial discharge of the electronic device based on samples from the first analog to digital converter, determine a leakage current of the electronic device based on samples from the second analog to digital converter, and determine an arc current of the electronic device based on samples from the third analog to digital converter.

17. A method, comprising:
applying an AC input signal to a first socket terminal of a socket;
determining a partial discharge of an electronic device installed in the socket based on a high pass filtered voltage of a second socket terminal responsive to application of the AC input signal to the first socket terminal; and
concurrently with determining the partial discharge, determining a leakage current of the electronic device based on a low pass filtered voltage of the second socket terminal responsive to application of the AC input signal to the first socket terminal.

18. The method of claim 17, further comprising, concurrently with determining the partial discharge and the leakage current, determining an arc current of the electronic device based on a high pass filtered voltage of a clamp circuit coupled between the second socket terminal and the reference node responsive to application of the AC input signal to the first socket terminal.

19. The method of claim 18, further comprising high pass filtering the voltage of the clamp circuit at a cutoff frequency of approximately 1 MHz or more.

20. The method of claim 18, further comprising, concurrently with determining the partial discharge and the leakage current, determining a stress voltage of the electronic device based on a low pass filtered voltage of the first socket terminal responsive to application of the AC input signal to the first socket terminal.

21. The method of claim 20, further comprising low pass filtering the voltage of the first socket terminal at a cutoff frequency of approximately 100 Hz or less.

22. The method of claim 17, further comprising
high pass filtering the voltage of the second socket terminal at a cutoff frequency of approximately 1 MHz or more to provide a high pass filtered signal;
determining the partial discharge of the electronic device based on the high pass filtered signal;
low pass filtering the voltage of the second socket terminal at a cutoff frequency of approximately 100 Hz or less to provide a low pass filtered signal; and
determining the leakage current of the electronic device based on the low pass filtered signal.

23. The method of claim 17, further comprising, concurrently with determining the partial discharge and the leakage current, determining a stress voltage of the electronic device based on a low pass filtered voltage of the first socket terminal responsive to application of the AC input signal to the first socket terminal.

24. The method of claim 17, further comprising applying the AC input signal at a single amplitude.

25. The method of claim 24, further comprising applying the AC input signal with a spike for partial discharge testing.
